(19) United States
(12) Patent Application Publication
(10) Pub. No.: US 2026/0206352 A1
(43) Pub. Date: Jul. 16, 2026

(54) IMAGE SENSOR PACKAGES AND RELATED METHODS

(71) Applicant: SEMICONDUCTOR COMPONENTS INDUSTRIES, LLC, Scottsdale, AZ (US)

(72) Inventor: Shou-Chian HSU, Zhubei City (TW)

(73) Assignee: SEMICONDUCTOR COMPONENTS INDUSTRIES, LLC, Scottsdale, AZ (US)

(21) Appl. No.: 19/019,996

(22) Filed: Jan. 14, 2025

(51) Int. Cl. H10F 39/00; H01L 23/00; H10F 71/00

(52) U.S. Cl. CPC H10F 39/811; H10F 39/024; H10F 39/804; H10F 71/136; H10W 80/312; H10W 80/327; H10W 90/794

(57) ABSTRACT

An image sensor package may include an image sensor semiconductor die including at least one pad; a carrier die including a through silicon via; and an optically transmissive cover bonded to the image sensor semiconductor die. The through silicon via may be bonded to the at least one pad. The carrier die may include only electrical connectors.

### BACKGROUND

### 1. Technical Field

Aspects of this document relate generally to image sensors. More specific implementations involve backside integrated image sensor packages.

### 2. Background

Various semiconductor packages have been developed that work to protect a semiconductor die contained therein from shock or vibration. Other semiconductor packages have been developed to protect a semiconductor die from electrostatic discharge. Yet other semiconductor packages work to provide mechanical support to a semiconductor die included therein.

### SUMMARY

An image sensor package may include an image sensor semiconductor die including at least one pad; a carrier die including a through silicon via; and an optically transmissive cover bonded to the image sensor semiconductor die. The through silicon via may be bonded to the at least one pad. The carrier die may include only electrical connectors.

Implementations of an image sensor package may include one, all, or any of the following:

The electrical connectors form a redistribution layer.

The through silicon via may be included only in the carrier die.

The image sensor semiconductor die may be a backside integrated image sensor semiconductor die.

The pad of the through silicon via may be hybrid bonded to the at least one pad of the image sensor semiconductor die.

An air gap may be present between the optically transmissive cover and the image sensor semiconductor die.

The image sensor package may be gapless.

Implementations of a method of forming an image sensor package may include providing a semiconductor substrate; providing a carrier substrate; forming a plurality of through silicon vias in the carrier substrate; and forming a dielectric layer on the carrier substrate. The method may include forming a plurality of via pads, each via pad of the plurality of via pads on each through silicon via of the plurality of through silicon vias; and forming a device layer on the semiconductor substrate, the device layer including a plurality of interconnect pads. The method may include bonding the carrier substrate to the semiconductor substrate at the plurality of via pads and plurality of interconnect pads; thinning the semiconductor substrate to a desired thickness; and bonding an optically transmissive substrate over the semiconductor substrate. The method may include thinning the carrier substrate to the plurality of through silicon vias; forming electrical connectors on the carrier substrate to the plurality of through silicon vias; and singulating the semiconductor substrate, carrier substrate, and optically transmissive substrate to form a plurality of image sensor packages.

Implementations of an method of forming an image sensor package may include one, all, or any of the following:

The electrical connectors may form a redistribution layer.

The method may include adjusting a warpage of the carrier substrate to correspond with a warpage of the semiconductor substrate before bonding the carrier substrate to the semiconductor substrate.

Adjusting the warpage of the carrier substrate further may include thinning the carrier substrate to a first desired thickness.

Adjusting the warpage of the carrier substrate further may include thinning the carrier substrate to a first desired thickness before forming the plurality of through silicon vias in the carrier substrate.

Adjusting the warpage of the carrier substrate further may include adjusting a plasma or a pressure during etching of the plurality of through silicon vias.

Adjusting the warpage of the carrier substrate further may include annealing the carrier substrate after forming the plurality of through silicon vias.

The method may include forming a color filter array and microlenses over a pixel region of each image sensor included in the device layer.

Implementations of a method of forming an image sensor package may include providing a carrier substrate; providing an image sensor substrate including a plurality of interconnect pads; and forming a plurality of through silicon vias in the carrier substrate. The method may include forming a plurality of via pads, each via pad of the plurality of via pads on each through silicon via of the plurality of through silicon vias; bonding the carrier substrate to the image sensor substrate at the plurality of via pads and plurality of interconnect pads; and thinning the image sensor substrate to a desired thickness. The method may include bonding an optically transmissive substrate over the image sensor substrate; thinning the carrier substrate to the plurality of through silicon vias; and forming electrical connectors on the carrier substrate to the plurality of through silicon vias. The method may include singulating the image sensor substrate, carrier substrate, and optically transmissive substrate to form a plurality of image sensor packages.

Implementations of a method of forming an image sensor package may include one, all, or any of the following:

The method may include adjusting a warpage of the carrier substrate to correspond with a warpage of the image sensor substrate before bonding the carrier substrate to the image sensor substrate.

Adjusting the warpage of the carrier substrate further may include thinning the carrier substrate to a first desired thickness.

Adjusting the warpage of the carrier substrate further may include thinning the carrier substrate to a first desired thickness before forming the plurality of through silicon vias in the carrier substrate.

The method may include forming a color filter array and microlenses over a pixel region of each image sensor included in the image sensor substrate.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a backside integrated image sensor package;

FIG. 2 is side-by-side cross sectional views of an image sensor substrate and a carrier substrate;

FIG. 3 are cross sectional views of the image sensor substrate and carrier substrate of FIG. 2 following a device layer and through silicon vias, respectively;

FIG. 4 is a cross sectional view of the image sensor substrate and carrier substrate of FIG. 3 following a bonding operation;

FIG. 5 is a cross sectional view of the bonded image sensor substrate and carrier substrate of FIG. 4 following a thinning operation of the image sensor substrate;

FIG. 6 is a cross sectional view of the bonded image sensor substrate and carrier substrate of FIG. 5 following formation of microlenses;

FIG. 7 is a cross sectional view of the bonded image sensor substrate and carrier substrate of FIG. 6 following bonding of an optically transmissive substrate to the image sensor substrate;

FIG. 8 is a cross sectional view of the bonded image sensor substrate and carrier substrate of FIG. 7 following thinning of the carrier substrate to the through silicon vias;

FIG. 9 is a cross sectional view of the bonded image sensor substrate and carrier substrate of FIG. 8 following formation of electrical connectors on the carrier substrate; and

FIG. 10 are a cross sectional views of image sensor packages following singulation.

### DESCRIPTION

This disclosure, its aspects and implementations, are not limited to the specific components, assembly procedures or method elements disclosed herein. Many additional components, assembly procedures and/or method elements known in the art consistent with the intended image sensor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor packages, and implementing components and methods, consistent with the intended operation and methods.

In the manufacture of image sensor packages, through silicon vias are often employed. Since through silicon vias typically extend through the thickness of a semiconductor die or deeper into the thickness of a semiconductor die than the layers of semiconductor material formed on the die to form the semiconductor device (device layer), etching poses various technical challenges. Endpoint control/detection is challenging. One reason is that the etch stop for the through silicon via is typically a metal pad on the side of the semiconductor die opposite the side being etched. The thickness of the metal pad is often quite thin relative to the total thickness of the via, creating situations where attempting to use overetch times to ensure full etching of the vias results in damage to the metal pad, resulting in leakage, shorts, or opens in the via chain structure. Also, warpage of the semiconductor substrate itself affects the across and within substrate etching uniformity. While the use of overetching to account for the warpage to ensure full etching of all of the through silicon vias on a semiconductor substrate can be done, where the etch stop for each via is against a thin metal pad, the likelihood of creating electrical defects is significantly increased. Also, where the pitch and number of through silicon vias is increasing as the size of the image sensor devices on a given semiconductor substrate is shrinking/decreasing, warpage further frustrates attempts to have accurate etch endpoint control/detection needed to avoid creating electrical defects.

In this document, systems and processes are disclosed that provide better control of warpage or change the process in ways so that the previous warpage no longer affects the through silicon via etching process. As through silicon vias often involve etching through various semiconductor substrate materials and die stack materials which are not actually silicon, as used in this document, the term “through silicon via” includes a via structure that extends through a thickness of a semiconductor substrate even when that via extends through various die stack materials (like oxides or dielectrics) or through other semiconductor substrate materials including, by non-limiting example, silicon carbide, silicon-on-insulator, ruby, sapphire, gallium nitride, gallium arsenide, or other semiconductor materials.

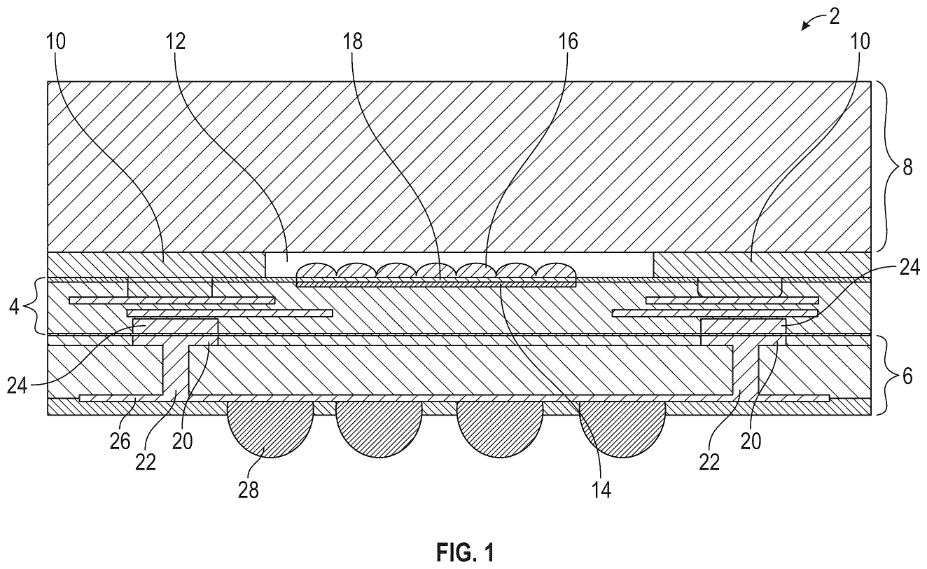

Referring to FIG. 1, a cross sectional view of an implementation of a backside integrated image sensor package 2 is illustrated. As illustrated, the package 2 includes an image sensor semiconductor die 4 bonded to a carrier die 6 and to an optically transmissive cover 8. In this implementation, the bond between the image sensor semiconductor die 4 and carrier die 6 is a hybrid bond involving metal interconnects bonded together. In some implementations, the hybrid bond may also include at least some bonding of dielectric or other materials that are contacted across the width of the image sensor semiconductor die 4 and carrier die 6. In this implementation, the hybrid bond includes a bond between pads 20 of through silicon vias 22 and corresponding pads 24 of the image sensor die 4.

The optically transmissive cover 8 is bonded to the image sensor semiconductor die 4 using a dam material 10 which may be an adhesive material in some package implementations. In other implementations, a separate adhesive material/layer may be employed in combination with the dam material 10. This structure forms an air gap 12 between the optically transmissive cover 8 and the pixel array 14 of the image sensor semiconductor die 4 in which microlenses 16 and a color filter array 18 extend above the pixel array 14. In other image sensor package implementations, however, the sensor may be a gapless image sensor which contains no air gap where the space in the gap illustrated in FIG. 1 is filled with a material of a desired refractive index.

The carrier die 6 includes the through silicon vias 22 and corresponding pads 20. The carrier die 6 also includes additional electrical connectors 26, 28 which form a redistribution layer that route electrical signals from the through silicon vias 22. In the implementation illustrated in FIG. 1, the electrical connectors 28 take the form of an array of balls which are designed to allow the image sensor package 2 to be attached to a circuit or motherboard. Note that in the image sensor package 2 implementation illustrated in FIG. 1 that the carrier die includes only electrical connectors (including the through silicon vias 22 and corresponding pads 20) and thus does not include any active semiconductor devices (transistors, etc.) formed therein/thereon. In various implementations, passive devices like resistors, capacitors, or inductors may be coupled thereto or formed thereon, but in this package implementation, the active semiconductor devices (transistors, pixels, etc.) are all contained only on the image sensor die 4. In some implementations, in addition to the carrier die, another semiconductor die may be bonded to the image sensor die which may be, by non-limiting example, a digital signal processor, memory, a microprocessor, or other semiconductor device type either prior to or after bonding with the carrier die.

Note that the image sensor semiconductor die 4 illustrated in FIG. 1 does not include any through silicon via structure, just the pads 24 aligned with the pads 20 of the through silicon vias 22 of the carrier die 6. Because of this, the image sensor semiconductor die 4 does not have to experience any direct etching related to the through silicon via formation process, which prevents the previously mentioned electrical problems that occur when overetching of the pads 24 occurs as a way to attempt to manage the warpage of the image sensor semiconductor substrate.

In the image sensor package implementation 2 illustrated in FIG. 1, the image sensor semiconductor die 4 is a backside integrated image sensor, meaning that light is detected entering a side of the image sensor from/through the material of the semiconductor substrate itself (back side) adjacent pixel devices formed in a device layer located on an opposing side of the image sensor (front side). While the use of backside integrated image sensor devices is illustrated in this document, in some package implementations, the techniques disclosed herein could be employed with front side integrated image sensors where the image sensor substrate is thinned prior to bonding to the carrier substrate as will be discussed hereafter. Where the image sensor is backside integrated, the material of the semiconductor substrate may be selected for its ability to allow transmission of the desired wavelength(s) of light that the pixel array has been designed to detect.

The various image sensor package implementations disclosed herein may be formed using various implementations of methods of forming an image sensor package. These methods will vary depending on whether the image sensor semiconductor die is backside integrated or frontside integrated as will be described hereafter.

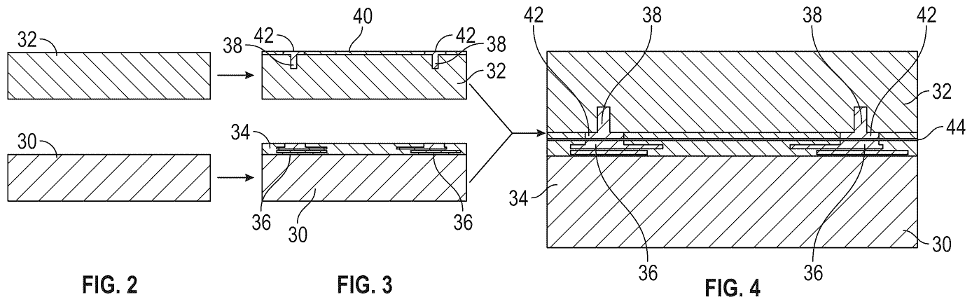

Referring to FIG. 2, an implementation of a semiconductor substrate (image sensor semiconductor substrate) 30 is illustrated along with an implementation of a carrier substrate 32. The semiconductor substrate 30 is illustrated at an initial stage of processing prior to formation of semiconductor devices thereon. FIG. 3 illustrates the semiconductor substrate 30 following the completion of various semiconductor processing operations that form various semiconductor devices thereon, including image sensor devices (pixels, etc.) in one or more layers of material that collectively are referred to herein as device layer 34. In this implementation, the semiconductor substrate 30 is illustrated at a full thickness, or the thickness at which it was processed through the various semiconductor process tools to form the layers and devices in the device layer 34. Where the image sensor devices included in the semiconductor substrate 30 are frontside integrated, the method implementations may include thinning the semiconductor substrate 30 to a desired thickness which leaves a plurality of interconnect pads 36 exposed. This thinning may take place using an edge ring method that allows the semiconductor substrate 30 to be able to be handled or the thinning may involve use of an additional carrier support during the thinning operation. The thinning takes place from the backside (not device side) of the semiconductor substrate 30.

FIG. 3 also illustrates the carrier substrate 32 following formation of through silicon vias 38 therein. The process of forming the through silicon vias on the carrier substrate 32 involves an alignment process to ensure a patterned layer formed on the carrier substrate 32 is properly aligned to correspond with/registered with the device layer 34 of the semiconductor substrate 30. In this way the patterned layer can be used in etching the through silicon vias in the desired locations that correspond with the interconnect pads 36 of the device layer 34. Note that the through silicon vias 38 illustrated in FIG. 3 do not extend all the way through the thickness of the carrier substrate 32 following etching and then filling with an appropriate desired electrically conductive material using sputtering, electroplating, electroless plating, chemical vapor deposition, or any combination thereof. This is because the carrier substrate 32 is also being processed at a full thickness, or at the ordinary thickness at which the substrate can be handled by semiconductor processing tools. Because of this, no significant warpage effects may be experienced during the through silicon via formation process, meaning that the through silicon vias have substantial uniformity in depth into the thickness of the carrier substrate 32 following the formation process. This ability to avoid etching and endpoint detection problems caused by forming through silicon vias in the semiconductor substrate 30 due to warpage thereof is one of the features of this particular method which decouples the formation of through silicon vias from the processing of the semiconductor substrate entirely. Also, where the image sensor devices in the semiconductor substrate are backside integrated, at the point in the process illustrated in FIG. 3, the semiconductor substrate 30 and the carrier substrate 32 are still at full thickness, meaning warpage effects can be minimized as much as possible through the bulk of the respective substrate materials. For the through silicon via formation process, the ability to have minimal warpage effects can help with achieving much higher densities. Also, since no through silicon via etching takes place on the semiconductor substrate at all, the etching process does not create the electrical defects in the through silicon via circuit that overetching of pads in the device layer can.

In various method implementations, following the formation of the through silicon vias (or prior to), a dielectric layer 40 is formed on the carrier substrate 32 to assist with electrically isolating the various through silicon vias 38 from each other. Also in various method implementations, either prior to the formation of the dielectric layer 40 or after, a set of via pads 42 are formed, each via pad 42 formed on a corresponding through silicon via 38. The via pads 42 are electrically isolated through the dielectric layer 40. In some implementations, no dielectric layer 40 may be formed, but the via pads 42 may be formed into corresponding recesses in the material of the carrier substrate 32 located around the through silicon vias. In such implementations, the material of the carrier substrate 32 itself is used to provide electrical isolation and bonding as needed. In such implementations, where the carrier substrate 32 is formed of an electrically insulative material like a glass or ceramic, the need for a separate dielectric layer may not be necessary. In some implementations, where the through silicon via includes copper, a barrier layer may be deposited in the through silicon vias 38 and/or around the via pads 42 to prevent migration of the copper through the material of the carrier substrate 32 into the device layer 34 of the semiconductor substrate 30.

In the various implementations disclosed herein, the carrier substrate 32 may be made of any of a wide variety of materials including, by non-limiting example, silicon, silicon carbide, silicon-on-insulator, ruby, sapphire, glass, silicon dioxide, gallium nitride, gallium arsenide, alumina, aluminum nitride, or any other material in which the through silicon vias can be formed and which has desired mechanical properties for supporting the semiconductor substrate. The particular material of the carrier substrate may also be chosen to help reach the desired electrical and/or thermal characteristics of the image sensor package.

At this point the carrier substrate 32 and semiconductor substrate 30 are ready to be bonded using a hybrid bond using at least the via pads 42 and the interconnect pads 36, respectively. If a dielectric layer 40 is present on the carrier substrate 32, at least some of the dielectric material may also bond with corresponding material in the device layer 34. Various methods of forming the hybrid bond can be utilized depending on the material types of the various pads and dielectric materials involved in the bond. In FIG. 4, the location of the hybrid bond is represented using a layer 44 though this may not be how the actual structure appears in an actual photomicrograph cross sectional view. FIG. 4 also illustrates how the via pads 42 and the interconnect pads 36 are aligned with one another following the bonding process is completed. Here, the other elements of the device layer 34 are also visible which also shows that none of the through silicon via structure 38 actually extends into the device layer 34.

The bonding process also allows for correction of warpage present in the semiconductor substrate 30 following formation of the device layer 34 using the flatness of the carrier substrate 32. This can be accomplished whether the semiconductor substrate 30 remains at a full thickness (as in the backside integrated image sensor case) or has already been thinned prior to bonding (in the frontside integrated image sensor case). This ability to correct warpage means that the resulting image sensor packages will be flatter/less warped than image sensor packages where the through silicon vias are formed in the semiconductor substrate directly and which lack any additional bonding process.

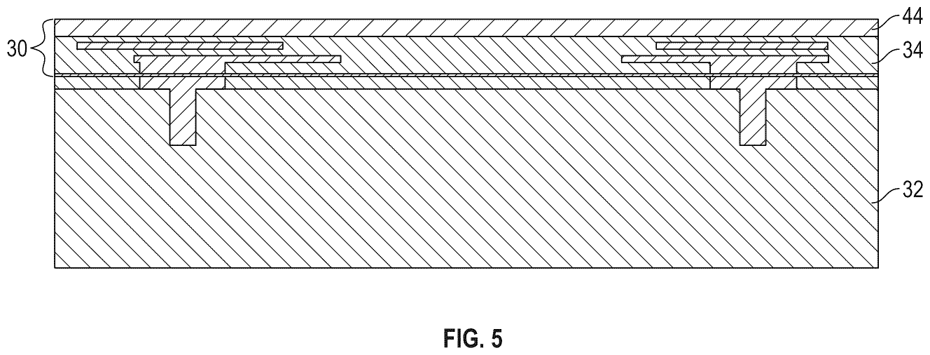

Referring to FIG. 5, the now bonded semiconductor substrate 30 and carrier substrate 32 are illustrated following completion of a thinning process of the semiconductor substrate 30 to a desired thickness. Here the remaining layer of semiconductor substrate material 44 contains portions of the pixel array of photodiodes formed which are now ready to receive the desired wavelength(s) of light that pass through the material of the semiconductor substrate 30 itself. The semiconductor substrate 30 is supported and retained in a flat orientation through the hybrid bond to the full thickness carrier substrate 32.

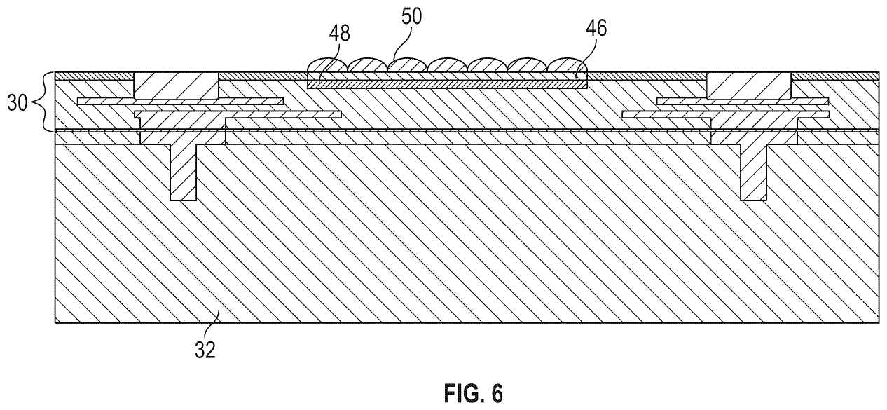

Following the thinning of the semiconductor substrate 30, additional structures can be formed on the semiconductor substrate 30 as part of the image sensor packaging process. FIG. 6 illustrates the semiconductor substrate 30 and carrier substrate 32 following formation of a color filter array 46 over the pixel array 48. On the color filter array 46 a set of microlenses 50 have been formed. While the processes for forming a color filter array 46 and microlenses 50 are illustrated in this particular method implementation, in other method implementations only a color filter array or only microlenses may be formed. In yet other implementations, no color filter array or microlenses may be formed. In some implementations where a gapless image sensor is formed, at this point a material of a desired refractive index is then applied over the semiconductor substrate 30 in preparation for/or after application of a dam material.

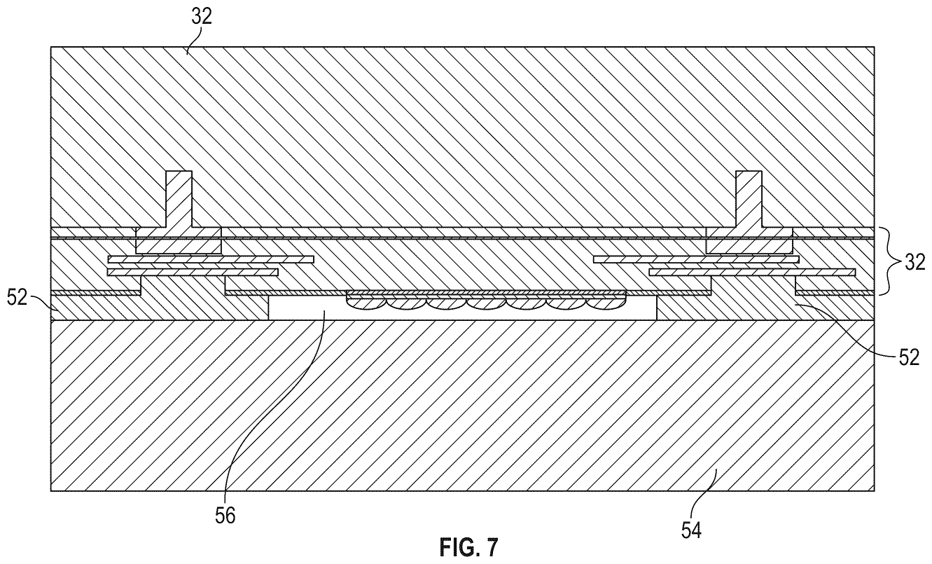

Referring to FIG. 7, the bonded semiconductor substrate 30 and carrier substrate 32 are illustrated following application/formation of a dam 52 to which an optically transmissive substrate 54 has been bonded/coupled. As previously described, where the material of the dam 52 is an adhesive material, the dam 52 forms the mechanical bond between the optically transmissive substrate 54 and the surface of the semiconductor substrate 30. Here the air gap 56 has been formed in the process of bonding the optically transmissive substrate 54 to the semiconductor substrate 30. In a gapless image sensor, the material with a desired refractive index would be present in this area instead and may act as the bonding material in the place of dam 52.

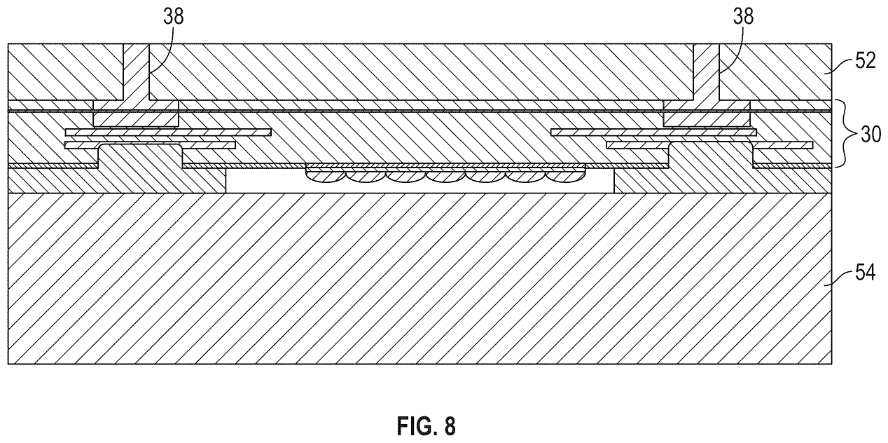

Following the bonding of the optically transmissive substrate 54 to the semiconductor substrate 30, the carrier substrate 32 is ready to be thinned. Referring to FIG. 8, the carrier substrate 32 is illustrated following thinning to the through silicon vias 38. Here the appropriate thinning process for the material of the carrier substrate 32 has been used to ensure that ends of the through silicon vias 38 are exposed through the material of the carrier substrate 32. The thickness of the optically transmissive substrate 54 is used as the support for the carrier substrate 32 and semiconductor substrate 30 during the thinning process. Depending on how the thinning process is carried out, the thinning may be concluded as the ends of the through silicon vias 38 are exposed or may finish when a predetermined thickness of the carrier substrate 32 has been removed, thus ensuring some of the material of the ends of the through silicon vias 38 are removed. Whether either process is utilized depends on the shape of the ends of the through silicon vias and the uniformity of the coverage of the metal/electrically conductive material present at the ends of the vias 38 in various implementations.

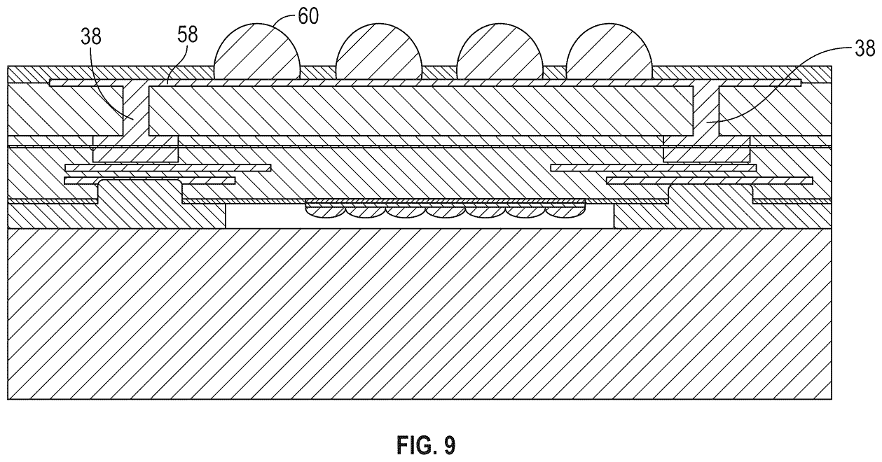

With the ends of the through silicon vias 38 exposed, the carrier substrate 32 is now ready for additional interconnect formation operations that will form electrical connections between the through silicon vias 38 and a circuit or motherboard. FIG. 9 illustrates the carrier substrate 32 following formation of electrical interconnects 58, 60 that connect the through silicon vias 38 with balls 60 allowing the image sensor packages to be attached to a circuit or motherboard. A wide variety of techniques can be employed to form the various interconnects consistent with the materials thereof and the pattern desired to be formed in various method implementations. For example, electrical interconnects 58 may be formed using a sputtering process used to form a seed layer upon which the metal of the electrical interconnects is electroplated. A patterned layer is then formed over the electroplated layer followed by an etching process (which may be a wet etching process in various implementations) that forms traces and openings for the bumps 60. Following removal of the patterned layer and the remaining seed layer, the bumps 60 are then dropped/formed in the corresponding openings. A wide variety of interconnect formation techniques may be employed in various method implementations to form the desired pattern of electrical interconnects. In some implementations, a substrate with an existing pattern may be bonded/soldered/sintered to the ends of the through silicon vias 38 instead of/in addition to forming a redistribution layer. The substrate may, in some implementations, include an embedded semiconductor die and/or may include multiple layers of electrically conductive/insulative material that provide electrical routing. Many possibilities for electrical interconnects exist using the principles disclosed in this document.

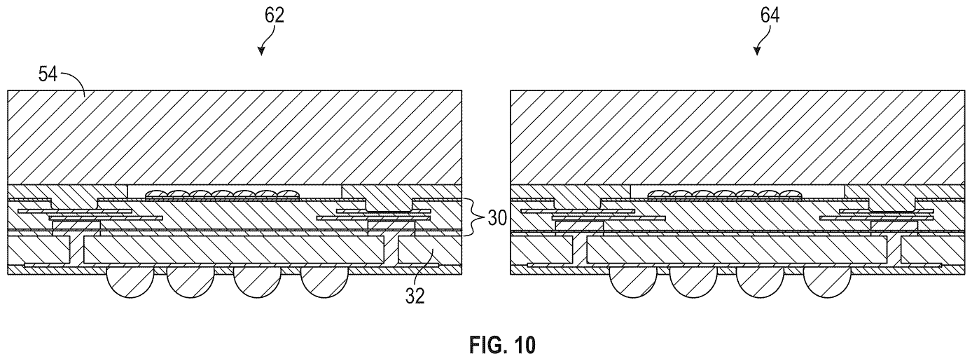

Following the formation of the electrical interconnects, FIG. 10 illustrates two image sensor semiconductor packages 62, 64 following singulation of the carrier substrate 32, semiconductor substrate 30, and optically transmissive substrate 54 of each. The singulation may be carried out using sawing, lasering, water jet cutting, or any combination thereof. At this point the packaging process may be completed, or other steps, including molding with a mold compound or others may be carried out depending on the final package design.

In places where the description above refers to particular implementations of image sensor packages and implementing components, sub-components, methods and sub-methods, it should be readily apparent that a number of modifications may be made without departing from the spirit thereof and that these implementations, implementing components, sub-components, methods and sub-methods may be applied to other image sensor packages.

What is claimed is:

1. An image sensor package comprising:
an image sensor semiconductor die comprising at least one pad;
a carrier die comprising a through silicon via; and
an optically transmissive cover bonded to the image sensor semiconductor die;
wherein the through silicon via is bonded to the at least one pad; and
wherein the carrier die comprises only electrical connectors.

2. The package of claim 1, wherein the electrical connectors form a redistribution layer.

3. The package of claim 1, where the through silicon via is comprised only in the carrier die.

4. The package of claim 1, wherein the image sensor semiconductor die is a backside integrated image sensor semiconductor die.

5. The package of claim 1, wherein a pad of the through silicon via is hybrid bonded to the at least one pad of the image sensor semiconductor die.

6. The package of claim 1, wherein an air gap is present between the optically transmissive cover and the image sensor semiconductor die.

7. The package of claim 1, wherein the image sensor package is gapless.

8. A method of forming an image sensor package, the method comprising:
providing a semiconductor substrate;
providing a carrier substrate;
forming a plurality of through silicon vias in the carrier substrate;
forming a dielectric layer on the carrier substrate;
forming a plurality of via pads, each via pad of the plurality of via pads on each through silicon via of the plurality of through silicon vias;
forming a device layer on the semiconductor substrate, the device layer comprising a plurality of interconnect pads;
bonding the carrier substrate to the semiconductor substrate at the plurality of via pads and plurality of interconnect pads;
thinning the semiconductor substrate to a desired thickness;
bonding an optically transmissive substrate over the semiconductor substrate;
thinning the carrier substrate to the plurality of through silicon vias;
forming electrical connectors on the carrier substrate to the plurality of through silicon vias; and
singulating the semiconductor substrate, carrier substrate, and optically transmissive substrate to form a plurality of image sensor packages.

9. The method of claim 8, wherein the electrical connectors form a redistribution layer.

10. The method of claim 8, further comprising adjusting a warpage of the carrier substrate to correspond with a warpage of the semiconductor substrate before bonding the carrier substrate to the semiconductor substrate.

11. The method of claim 10, wherein adjusting the warpage of the carrier substrate further comprises thinning the carrier substrate to a first desired thickness.

12. The method of claim 10, wherein adjusting the warpage of the carrier substrate further comprises thinning the carrier substrate to a first desired thickness before forming the plurality of through silicon vias in the carrier substrate.

13. The method of claim 10, wherein adjusting the warpage of the carrier substrate further comprises adjusting a plasma or a pressure during etching of the plurality of through silicon vias.

14. The method of claim 10, wherein adjusting the warpage of the carrier substrate further comprises annealing the carrier substrate after forming the plurality of through silicon vias.

15. The method of claim 8, further comprising forming a color filter array and microlenses over a pixel region of each image sensor comprised in the device layer.

16. A method of forming an image sensor package, the method comprising:
providing a carrier substrate;
providing an image sensor substrate comprising a plurality of interconnect pads;
forming a plurality of through silicon vias in the carrier substrate;
forming a plurality of via pads, each via pad of the plurality of via pads on each through silicon via of the plurality of through silicon vias;
bonding the carrier substrate to the image sensor substrate at the plurality of via pads and plurality of interconnect pads;
thinning the image sensor substrate to a desired thickness;
bonding an optically transmissive substrate over the image sensor substrate;
thinning the carrier substrate to the plurality of through silicon vias;
forming electrical connectors on the carrier substrate to the plurality of through silicon vias; and
singulating the image sensor substrate, carrier substrate, and optically transmissive substrate to form a plurality of image sensor packages.

17. The method of claim 16, further comprising adjusting a warpage of the carrier substrate to correspond with a warpage of the image sensor substrate before bonding the carrier substrate to the image sensor substrate.

18. The method of claim 17, wherein adjusting the warpage of the carrier substrate further comprises thinning the carrier substrate to a first desired thickness.

19. The method of claim 17, wherein adjusting the warpage of the carrier substrate further comprises thinning the carrier substrate to a first desired thickness before forming the plurality of through silicon vias in the carrier substrate.

20. The method of claim 16, further comprising forming a color filter array and microlenses over a pixel region of each image sensor comprised in the image sensor substrate.
